(19) United States
(12) Patent Application Publication
(10) Pub. No.: US 2009/0035935 A1
(43) Pub. Date: Feb. 5, 2009

(54) Method of forming a metal wiring

(76) Inventors: Hea-Ki Kim, Suwon-si (KR); Dong-Chul Hur, Seongnam-si (KR); Mo-Hyun Cho, Suwon-si (KR); Duk-Sung Kim, Hwaseong-si (KR)

Correspondence Address: LEE & MORSE, P.C., 3141 FAIRVIEW PARK DRIVE, SUITE 500, FALLS CHURCH, VA, 22042, US

(21) Appl. No.: 12/222,062

(22) Filed: Jul. 31, 2008

(30) Foreign Application Priority Data
Aug. 1, 2007 (KR) 10-2007-0077267

(51) Int. Cl. H01L 21/4763

(52) U.S. Cl. 438/643; 257/E21.495

(57) ABSTRACT

A method of forming a metal wiring for a semiconductor device includes forming a metal-based layer on a substrate, the substrate including at least one conductive structure, forming a metal seed layer on the metal-based layer, forming a supplementary contact layer on the metal seed layer along peripheral portions of the substrate, the metal seed layer being between the substrate and the supplementary contact layer, and the supplementary contact layer including a supplementary metal having an electrical resistance smaller than or equal to an electrical resistance of the metal seed layer, loading the substrate into a plating apparatus, such that the supplementary contact layer is being in direct contact with the cathode of the plating apparatus, and performing an electroplating process on the metal seed layer to form a metal wiring layer on the metal-based layer.

### BACKGROUND OF THE INVENTION

1. Field of the Invention

Example embodiments of the present invention relate to a method of forming a metal wiring. More particularly, example embodiments of the present invention relate to a method of forming a metal wiring for a semiconductor device by an electroplating process.

2. Description of the Related Art

Semiconductor devices may include discrete devices, e.g., transistors, electrically connected to each other by metal wirings. The metal wirings may include aluminum wirings, e.g., wirings formed of aluminum on a semiconductor substrate by a photolithography process against an aluminum layer on the substrate, copper wirings, and so forth. For example, minute metal wirings in highly integrated semiconductor devices may include copper wirings due to smaller electrical resistance and smaller resistance related to electrical migration (EM) of the copper wirings as compared to, e.g., aluminum wirings. The smaller electrical resistance of the copper wirings may increase electrical reliability of wirings in highly integrated semiconductor devices, e.g., wirings having increased length and reduced cross-section due to increased integration.

A conventional wiring, e.g., a copper wiring, may be formed by patterning a metal layer, e.g., by a damascene process. The metal layer, e.g., a copper layer, may be deposited by, e.g., a chemical vapor deposition (CVD) process, a physical vapor deposition (PVD) process, an electroless plating (ELP) process, an electroplating (EP) process, and so forth. For example, if a copper layer is deposited by the EP process, a resultant copper layer may have a substantially same impurity degree as a copper layer formed by the PVD process, while having lower deposition costs and superior wiring characteristics. In addition, a copper layer formed by the EP process may be crystallized along a direction of a lattice face, i.e., 111 face, to have a small grain boundary and a dense structure, thereby exhibiting good electrical resistance related to EM.

In a conventional EP process, a substrate may be coated with a metal seed layer, and may be connected to a cathode via the metal seed layer. The substrate may be contacted by a plating solution, so upon electrical contact of the substrate and the plating solution with the cathode and an anode, respectively, metal ions from the plating solution may be extracted to form a metal layer on the metal seed layer.

The conventional metal seed layer, however, may be in direct contact with the cathode, so a portion of the metal seed layer in contact with the cathode may be partially etched off due to a bipolar effect. Accordingly, an electrical contact between the cathode and the substrate via the metal seed layer may be partially broken during the EP process, so current density on the substrate may be non-uniform. Non-uniform current density on the substrate may cause non-uniform extraction and deposition of metal on the substrate, so quality of the resultant metal layer may be deteriorated. Further, as a degree of integration of semiconductor devices increases, thickness of the metal seed layer may decrease and non-uniformity of current density therethrough may increase.

### SUMMARY OF THE INVENTION

Embodiments of the present invention are therefore directed to a method of forming a metal wiring for a semiconductor device, which substantially overcomes one or more of the disadvantages of the related art.

It is therefore a feature of an embodiment of the present invention to provide a method of forming a metal wiring having a substantially uniform thickness by an electroplating process.

At least one of the above and other features and advantages of the present invention may be realized by providing a method of forming a metal wiring for a semiconductor device, including forming a metal-based layer on a substrate, the substrate including at least one conductive structure, forming a metal seed layer on the metal-based layer, forming a supplementary contact layer on the metal seed layer along peripheral portions of the substrate, the supplementary contact layer including a supplementary metal having an electrical resistance smaller than or equal to an electrical resistance of the metal seed layer, loading the substrate into a plating apparatus, such that the supplementary contact may be in direct contact with a cathode of the plating apparatus, and forming the metal wiring layer on the metal-based layer by an electroplating process.

The method may further include forming an insulation layer between the substrate and the metal-based layer. The method may further include forming a contact hole through the insulation layer to partially expose the at least one conductive structure, the metal-based layer being conformally formed on the insulation layer. Forming the metal-based layer may include forming an anti-diffusion layer on the insulation layer. Forming the metal-based layer may include forming at least one metal layer on the insulation layer, the metal layer including one or more of tungsten (W), titanium (Ti), tantalum (Ta), tungsten nitride (WN), titanium nitride (TiN), and tantalum nitride (TaN). Forming the metal-based layer and the metal seed layer may include using an atomic layer deposition (ALD) process, a sputtering process, and/or a cyclic chemical vapor deposition (CVD) process.

Forming the supplementary contact layer may include plating the supplementary metal on the metal seed layer along the peripheral portions of the substrate by an electroless plating (ELP) process using a plating solution, the plating solution including a mixture of a salt of the supplementary metal and a reducing agent having weaker reducing ability than the supplementary metal, and removing a residue of the plating solution from the peripheral portions of the substrate. Plating the supplementary metal on the metal seed layer by the ELP process may include securing the substrate to a rotation chuck, arranging an injection nozzle over the peripheral portion of the substrate, the injection nozzle being connected to a reservoir including the plating solution, and injecting the plating solution onto the metal seed layer while rotating the substrate. Plating the supplementary metal on the metal seed layer by the ELP process may include immersing the peripheral portion of the substrate into a reservoir including the plating solution, and rotating the reservoir while the substrate remains stationary. The supplementary metal may include one or more of copper (Cu), nickel (Ni), cobalt (Co), and palladium (Pd), and the reducing agent may include one or more of sodium borohydride, sodium hypophosphite, formalin, hydrazine sulfate, formate, dimethylamine borane (DMAB), diethylamine borane (DEAB), and triethylamine borane (TEAB). The metal seed layer and the supplementary contact layer may be formed of a substantially same material. Removing the residue of the plating solution includes supplying pure water onto the peripheral portions of the substrate.

Prior to plating the supplementary metal on the metal seed layer, the method may further include removing a native oxide layer from the metal seed layer, activating peripheral portions of the metal seed layer on corresponding peripheral portions of the substrates, and forming at least one plating nucleus on the peripheral portions of the metal seed layer. Activating the peripheral portions of the metal seed layer may include activating surface energy of the peripheral portions of the metal seed layer by a plasma treatment. The plasma treatment may be performed using one or more of nitrogen (N₂), hydrogen (H₂), oxygen (O₂), and argon (Ar). Forming the plating nucleus may include immersing the activated metal seed layer into an aqueous solution with a nuclear material having smaller ionization tendency than the metal seed layer. The nuclear material may include palladium (Pd). Removing the native oxide layer from the metal seed layer may include injecting an alkaline solution onto the peripheral portions of the substrate. The alkaline solution may include an aqueous malic acid solution or an aqueous malonic acid solution. After forming the metal wiring layer, the method may further include forming a contact plug on the substrate by partially removing the metal-based layer and the metal wiring layer from the substrate, and forming a protective layer on the contact plug. Forming the protective layer may include forming a silver thin layer on the contact plug by a substitution reaction through an ELP process.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1A-1F illustrate sequential cross-sectional views of a method of forming a metal wiring for a semiconductor device in accordance with an example embodiment of the present invention;

FIG. 2 illustrates an enlarged perspective view of a cathode in the EP apparatus of FIG. 1D; and

FIGS. 3A-3B illustrate current density distribution on a substrate according to an embodiment of the present invention and a comparative substrate, respectively.

### DETAILED DESCRIPTION OF THE INVENTION

Korean Patent Application No. 10-2007-77267, filed on Aug. 1, 2007, in the Korean Intellectual Property Office, and entitled: “Method of Forming a Metal Wiring,” is incorporated by reference herein in its entirety.

Embodiments of the present invention will now be described more fully hereinafter with reference to the accompanying drawings, in which exemplary embodiments of the invention are illustrated. Aspects of the invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers, elements, and regions may be exaggerated for clarity of illustration. It will also be understood that when a layer or element is referred to as being “on” another layer, element, or substrate, it can be directly on the other layer, element, or substrate, or intervening layers and/or elements may also be present. Further, it will also be understood that when a layer or element is referred to as being “between” two layers or elements, it can be the only layer or element between the two layers or elements, or one or more intervening layers and/or elements may also be present. In addition, it will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like reference numerals refer to like elements throughout.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C” and “A, B, and/or C” includes the following meanings: A alone; B alone; C alone; both A and B together; both A and C together; both B and C together; and all three of A, B, and C together. Further, these expressions are open-ended, unless expressly designated to the contrary by their combination with the term “consisting of.” For example, the expression “at least one of A, B, and C” may also include an nth member, where n is greater than 3, whereas the expression “at least one selected from the group consisting of A, B, and C” does not.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise.

Example embodiments of the invention are described herein with reference to cross-sectional illustrations that are schematic illustrations of idealized example embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

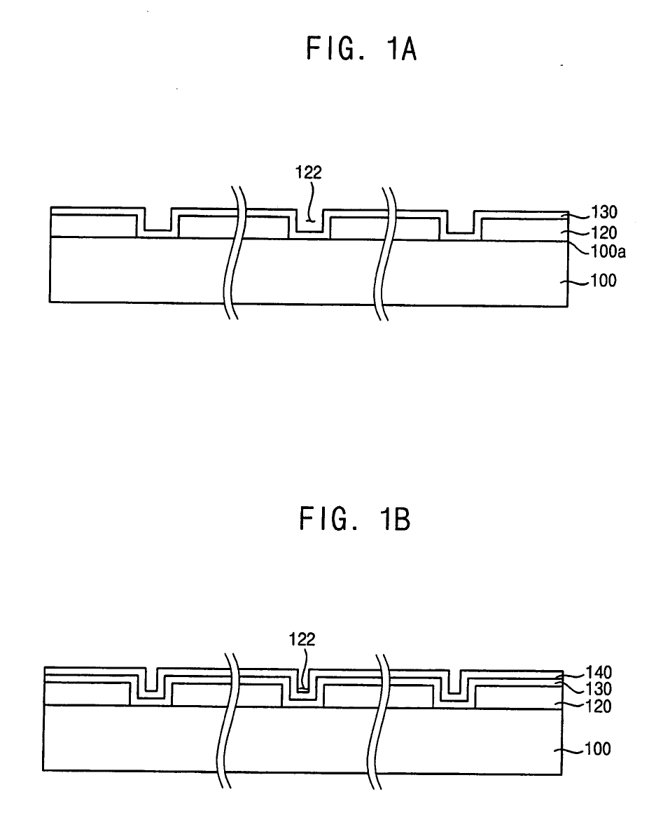

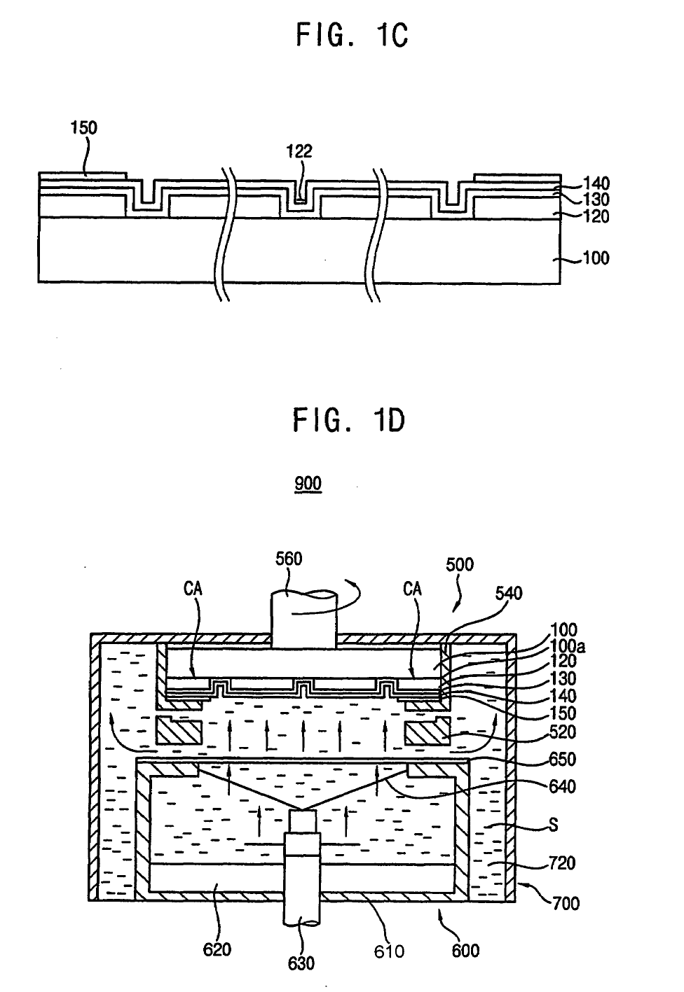

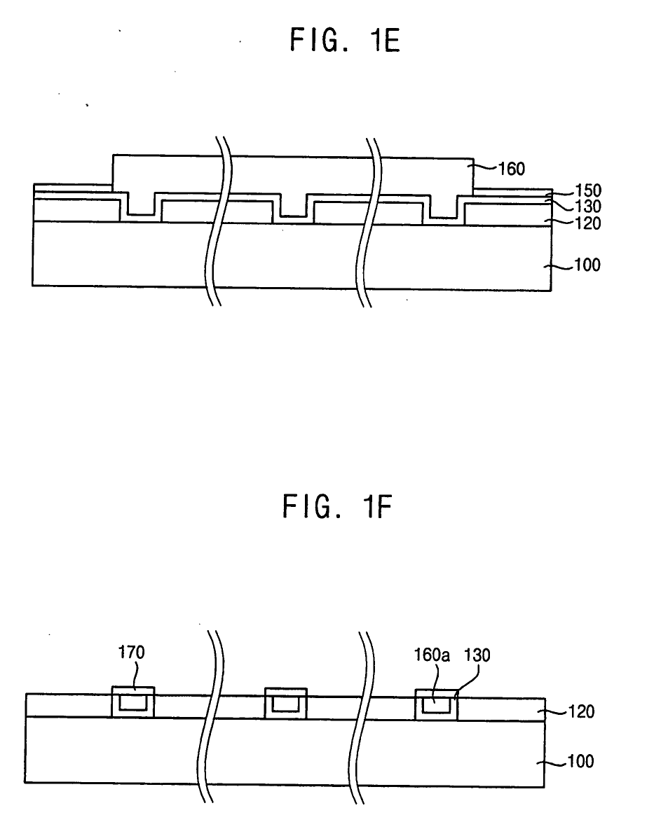

Hereinafter, the present invention will be explained in more detail below with reference to the accompanying drawings. FIGS. 1A-1F illustrate sequential cross-sectional views in a method of forming a wiring structure for a semiconductor device in accordance with an example embodiment of the present invention.

Referring to FIG. 1A, at least one conductive structure (not shown), e.g., an electrode structure or a lower wiring structure of a semiconductor memory device, may be formed on a substrate 100. An insulation interlayer 120 may be formed on an upper surface 100a of the substrate 100 to a sufficient thickness, i.e., as measured along a normal to the substrate 100, to cover the at least one conductive structure. The insulation interlayer 120 may include at least one opening 122 corresponding to the conductive structure, so the opening 122 may extend from an upper surface of the insulation interlayer 120 toward the substrate 100 to partially expose the corresponding conductive structure. For example, the insulation interlayer 120 may include a plurality of discrete segments spaced apart from each other on the substrate 100, so a space between two adjacent segments of the insulation interlayer 120 may define one opening 122. The opening 122 may be, e.g., a contact hole exposing a transistor, a via-hole exposing a lower wiring structure, and so forth. The substrate 100 may include a plurality of conductive structure, so the insulation interlayer 120 may include a plurality of openings 120 corresponding to the plurality of conductive structures.

A metal-based layer 130 may be conformally formed on the insulation interlayer 120. The term “conformally” corresponds to a layer formed with a uniform thickness or substantially uniform thickness along a profile of an underlying layer or structure. Accordingly, the metal-based layer 130 may be continuously formed on the insulation interlayer 120, on inner sidewalls of the openings 122, and on a surface of the conductive structure exposed through the opening 122.

The metal-based layer 130 may be formed of, e.g., a metal layer and/or a metal composition layer, by an atomic layer deposition (ALD) process, a sputtering process, or a cyclic chemical vapor deposition (CVD) process. For example, the metal-based layer 130 may include a barrier layer, e.g., an anti-diffusion layer for preventing diffusion of metal from a metal plug 160a (FIG. 1F) into the insulation interlayer 120, and/or a glue layer for reducing electric resistance between the metal plug 160a and the conductive structure, and so forth. For example, the glue layer may include one or more of tungsten (W), titanium (Ti), and tantalum (Ta), and the anti-diffusion layer may include one or more of tungsten nitride (WN), titanium nitride (TiN), and tantalum nitride (TaN).

Referring to FIG. 1B, a metal seed layer 140 may be conformally formed on the metal-based layer 130, e.g., the metal seed layer 140 may be formed on the metal-based layer 130 along a surface profile of the insulation interlayer 120 having the opening 122, by an ALD process, a sputtering process, or a cyclic CVD process. The metal seed layer 140 may electrically connect the substrate 100 to a cathode to uniformly distribute electrical current on an entire surface of the substrate 100, as will be explained in more detail below. In addition, the metal seed layer 140 may function as a plating nucleus when metals are extracted from a plating solution. An electrical resistance of the metal seed layer 140 may be smaller than an electrical resistance of an extracted metal by an electroplating process, so that the metal seed layer 140 and the extracted metal deposited thereon may function as a metal wiring for a semiconductor device. For example, the metal seed layer 140 may include copper (Cu).

Referring to FIG. 4C, a supplementary contact layer 150 may be formed on the metal seed layer 140 in a peripheral portion of the substrate 100. For example, a supplementary contact layer 150 may extend from an outermost edge of the substrate 100 toward a center of the substrate to overlap a portion of a corresponding segment of the insulation interlayer 120, i.e., a segment extending from a same outermost edge of the substrate 100. A length of the supplementary contact layer 150 may be adjusted with respect to a size of a cathode, so the supplementary contact layer 150 may be formed to substantially cover a peripheral portion of the metal seed layer 140 to prevent direct contact between the metal seed layer 140 and the cathode, as will be explained in more detail below.

The supplementary contact layer 150 may be formed of a material having a lower or a substantially same electrical resistance than the electrical resistance of the metal seed layer 140, so a contact resistance between the metal seed layer 140 and the supplementary contact layer 150 may be varied in a predetermined range. The supplementary contact layer 150 may be formed to a predetermined thickness, i.e., a thickness sufficient to cover the metal seed layer 140 during an entire electroplating process and prevent etching of the metal seed layer 140. For example, the supplementary contact layer 150 may be formed to a thickness of about 1,000 angstroms to about 1,500 angstroms. It is noted, however, that the supplementary contact layer 150 may be etched, e.g., completely removed, during the electroplating process.

The supplementary contact layer 150 may be formed by an electroless plating (ELP) process in a separate apparatus prior to the electroplating process of the substrate 100. In other words, the substrate 100 with the metal-based layer 130 and the metal seed layer 140 may be loaded into an ELP process chamber, so peripheral portions of the substrate 100 may be contacted with a plating solution to form the supplementary contact layer 150 on the peripheral portions of the substrate 100. For example, the supplementary contact layer 150 may have a geometrical pattern corresponding to a geometrical structure of the substrate 100, e.g., the supplementary contact layer 150 may be formed along an entire perimeter of the substrate 100.

As exemplary process of forming the supplementary contact layer 150 may be as follows. The substrate 100 with the metal-based layer 130 and the metal seed layer 140 may be secured to a rotating chuck (not shown) of an ELP apparatus. A pre-cleaning process may be performed on peripheral portions of the substrate 100 to remove a native oxide layer from the metal seed layer 140. The pre-cleaning process may be performed by injecting an alkaline solution, e.g., an aqueous malic acid solution or an aqueous malonic acid solution, onto the peripheral portion of the substrate 100.

Next, portions of the metal seed layer 140 corresponding to peripheral portions of the substrate 100 may be activated, e.g., by a plasma process, so a plurality of plating nuclei may be formed on the activated portions of the metal seed layer 140 by an extraction process. The plasma may be generated from, e.g., one or more of nitrogen (N₂), hydrogen (H₂), oxygen (O₂), and argon (Ar), to activate surface energy of the metal seed layer 140. The plating nuclei may be formed by immersing the activated metal seed layer 140 into an aqueous solution, e.g., a solution including dissolved nuclear material. The nuclear material, e.g., palladium (Pd), may have a smaller ionization tendency than the metal seed layer 140, so the nuclear material may be extracted onto a surface of the metal seed layer 140 to form the plating nuclei thereon.

The pre-cleaning process, the activation of the metal seed layer 140 and the plating nuclear extraction process may be selectively performed in accordance with process conditions and environment. For example, when the metal seed layer 140 includes a substantially same material as the supplementary contact layer 150, the pre-cleaning process, the activation of the metal seed layer 140, and the plating nuclear extraction process may be omitted. Instead, an injection nozzle connected to a reservoir (not shown) including the plating solution may be arranged over the peripheral portion of the substrate 100. The plating solution may be injected onto a rotating substrate 100 from the injection nozzle, so metal may be extracted from the injection solution onto portions of the metal seed layer 140 to form the supplementary contact layer 150 along peripheral portions of the substrate 100, e.g., in a circular stripe pattern. Alternatively, peripheral portions of the substrate 100 may be immersed into a reservoir filled with the plating solution, followed by rotation of the reservoir, while the substrate 100 is maintained stationary, to form the supplementary contact layer 150 along peripheral portions of the substrate 100.

The plating solution for forming the supplementary contact layer 150, i.e., by either of the processes described previously, may include a mixture of a salt of a supplementary metal, i.e., metal to be included in the supplementary contact layer 150, and a reducing agent having good solubility and weaker reducing ability than the supplementary metal, so the supplementary metal may be extracted onto the metal seed layer 140 by a catalytic redox reaction. Examples of the supplementary metal may include one or more of copper (Cu), nickel (Ni), cobalt (Co), and palladium (Pd). Examples of the reducing agent may include one or more of sodium borohydride, sodium hypophosphite, formalin, hydrazine sulfate, formate, dimethylamine borane (DMAB), diethylamine borane (DEAB) and triethylamine borane (TEAB). For example, both the metal seed layer 140 and the supplementary contact layer 150 may include copper.

For example, an aqueous copper sulfate solution having a molecular weight of about 249.69 and five molecules of water of crystallization (CuSO₄.5H₂O) mixed with formalin, i.e., a reducing agent, may be used as the plating solution. The formalin may be about 40% aqueous solution of formaldehyde, and may have a strong reducing ability. The following redox reaction, i.e., reaction 1, may be generated between the metal seed layer 140 and the mixture of the aqueous copper sulfate solution and the formalin to extract copper onto the surface of the metal seed layer 140.

Cu²⁺+2HCHO+4OH⁻→Cu+2HCHO⁻+2H₂O Reaction 1

It is noted that while the present example embodiment discloses the catalytic redox reaction using copper (Cu) for the metal plating process, any other suitable plating process may be used in place of or in conjunction with the catalytic redox reaction, if the metal plating process is performed without any electric power. For example, a non-catalytic redox reaction or a substitution reaction may be used in place of the catalytic redox reaction. It is further noted that the supplementary contact layer 150 may be varied in accordance with the metal seed layer 140, the conditions of the ELP process, e.g., process environment, and the supplementary metal.

When the ELP process is completed and the supplementary contact layer 150 is formed on the metal seed layer 140, a post-cleaning process may be performed on the peripheral portion of the substrate 100 to remove residue of the plating solution from the peripheral portion of the substrate 100. For example, pure water may be supplied to the peripheral portion of the substrate 100 as the post-cleaning process. In addition, a heat treatment may be further performed on the peripheral portion of the substrate 100 during the post-cleaning process to stabilize the adherence of the supplementary contact layer 150 to the metal seed layer 140.

Referring to FIG. 1D, the substrate 100 including the metal seed layer 140 and the supplementary contact layer 150 may be secured to a clam shell 500 in an electroplating cell 900 of a plating apparatus to form an electroplated metal layer, e.g., a copper layer, on metal-based layer 130. As illustrated in FIG. 1D, an exemplary plating apparatus may include the electroplating cell 900. The electroplating cell 900 may include the clam shell 500 for securing the substrate 100 and an anode chamber 600 for supplying the plating solution for electroplating the upper surface 100a of the substrate 100.

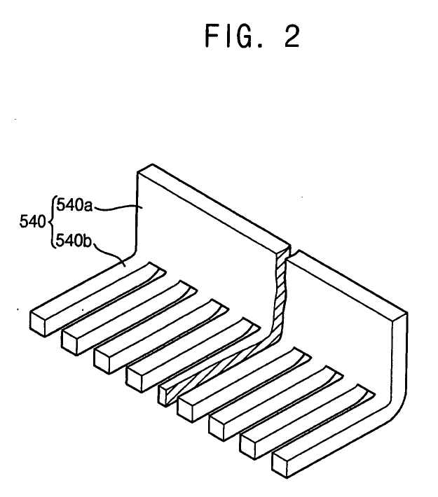

The clam shell 500 may include a lip seal 520 for determining a size of an electroplated metal layer to be formed and a cathode 540 integrally formed with the lip seal 520. The cathode 540 may apply electrical current to the substrate 100 during the electroplating process. For example, as illustrated in FIG. 2, the cathode 540 may include a cathode body 540a, e.g., a ring-shaped cathode body, and a plurality of contact nodes 1540b extending from a lower peripheral portion of the cathode body 540a to a lower central portion thereof. For example, the cathode body 540a and the plurality of contact nodes 1540b may be oriented in perpendicular planes with respect to each other. The contact nodes 540b may be formed of a conductive material, e.g., metal, and may be integrally formed with the cathode body 540a. The contact nodes 540b may be parallel to the lip seal 520 and may overlap a portion thereof.

The anode chamber 600 may include a chamber body 610 corresponding to the lip seal 520, a copper anode electrode 620 located at a bottom of the chamber body 610, a plating inlet 630 penetrating a central portion of the bottom of the chamber body 610, and an anode membrane 640 and a diffuser 650 at an upper portion of the chamber body 610.

The substrate 100 may be secured to the clam shell 500, so the substrate 100 may be positioned on the cathode 540 and the clam shell 500 may be coupled to the anode chamber 600. In particular, as illustrated in FIGS. 1D and 2, the upper surface 100a of the substrate 100 may be positioned on the contact nodes 540b and a sidewall of the substrate 100 may be in contact with the cathode body 540a, so the supplementary contact layer 150 may be in direct contact with the cathode 540. As illustrated in FIG. 1D, the supplementary contact layer 150 may be longer than a respective contact node 540b, so the supplementary contact layer 150 may shield the metal seed layer 140 from the contact node 540b. In other words, the supplementary contact layer 150 may be positioned in a contact area CA of the substrate 100 with the cathode 540, so the supplementary contact layer 150 may be between the contact node 540a of the cathode 540 and a portion of the metal seed layer 140 in the contact area CA. Accordingly, direct contact between the metal seed layer 140 and the contact node 540b may be prevented or substantially minimized during a subsequent electroplating process.

Once the substrate 100 is secured to the clam shell 500, an electroplating solution S may be supplied from the plating inlet 630. Electric power may be applied to the cathode 540 and the anode 620, so the substrate 100 may be negatively charged and the plating solution S may be positively charged. It is noted that the peripheral portions of the substrate 100 may include a contact portion to facilitate an electrical contact between the cathode 540 and the substrate 100. Accordingly, when the substrate 100 is loaded into the plating apparatus, the contact portion of the substrate 100 may contact a terminal of the cathode 540, so electrical current may pass from the cathode 540 to the substrate 100 through the contact portion of the substrate 100.

In particular, an electrical current may be applied to the metal seed layer 140 from the cathode 540 via the supplementary contact layer 150, and the metal seed layer 140 may uniformly distribute the electrical current on a substantially entire surface of the substrate 100. Accordingly, the metal ions, e.g., copper, in the plating solution S may be extracted uniformly toward the upper surface 100a of the substrate 100 by electrolysis to form a metal wiring layer 160 thereon, as illustrated in FIG. 1E. It is further noted that the lip seal 520 may be adjusted to control a size of the metal wiring layer 160, e.g., so the metal wiring layer 160 may not be coated on the contact area CA. The plating solution S provided into the clam shell 500 may be discharged through an outlet path 720.

As illustrated in FIG. 1E, the metal wiring layer 160 may be formed on the metal-based layer 130, and may completely fill the openings 122. As further illustrated in FIG. 1E, the metal wiring layer 160 may have a substantially uniform thickness. In particular, since the metal seed layer 140 may be sufficiently covered with the supplementary contact layer 150 during the entire electroplating process, the electrical contact between the cathode 540 and the substrate 100 may be stable, so the electrical current applied by the cathode 540 may be uniformly distributed on the entire surface of the substrate 100 through the metal seed layer 140. Since an extraction amount of metal on the substrate 100 is proportional to current density of the substrate 100 in the electroplating process, uniform current density on the substrate 100 may provide substantially uniform deposition of metal on the substrate 100 to form the metal wiring layer 160 with a substantially uniform thickness.

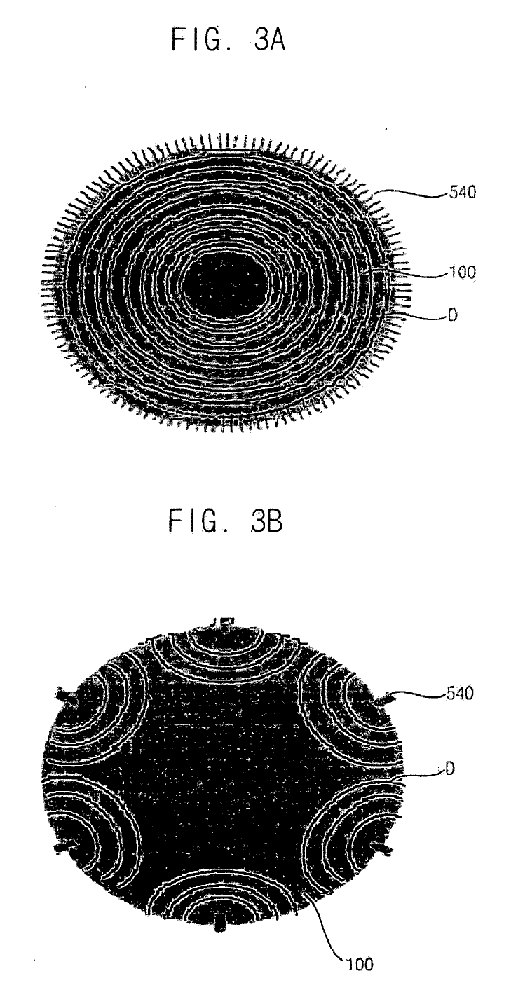

It is noted that if the electrical current were to be transferred from the cathode to the substrate via the metal seed 140 only, i.e., without the supplementary contact layer 150, a direct contact between the seed layer 140 and the cathode could have caused etching of the metal seed layer 140, thereby damaging an electrical connection between the substrate and the cathode. A damaged electrical connection between the substrate and the cathode may cause current concentration around the contact area CA of the substrate 100. In other words, increased current concentration around the CA area may cause non-uniform current density on the substrate 100, as illustrated in FIG. 3B, thereby increasing metal deposition around the contact area CA and causing non-uniform thickness of a resultant electroplated layer. Uniform current density on the substrate 100 may be achieved when the metal seed layer 140 is not deteriorated, i.e., shielded by the supplementary contact layer 150 according to embodiments of the present invention, and is illustrated in FIG. 3A. Current density in FIGS. 3A-3B is indicated by the character “D.” It is noted that a numerical value, as opposed to distribution, of current on the substrate 100 when current is applied through both the supplementary contact layer 150 and the metal seed layer 140 is substantially same as a numerical value of current on the substrate 100 when current is applied only through the metal seed layer 140.

Once the metal wiring layer 160 is formed, substrate 100 and the metal wiring layer 160 may be cleaned in a rinse cell (not shown). Referring to FIG. 4F, the supplementary contact layer 150, an upper portion of the metal-based layer 130, and an upper portion of the metal wiring layer 160 may be removed from the substrate 100 to form a contact plug 160a in the opening 122. In other words, upper surfaces of the contact plug 160a and the insulation interlayer 120 may be substantially level. The supplementary contact layer 150 may be removed, e.g., by a wet etching process, and the metal wiring layer 160 may be removed, e.g., by a chemical mechanical polishing (CMP) process or an etch-back process. As further illustrated in FIG. 1F, a protective layer 170 may be formed on the contact plug 160a, so the contact plug 160a may be prevented from being oxidized by oxygen (O₂) in ambient air. For example, the protective layer 170 may include a silver thin layer formed by a substitution reaction through an ELP process. The metal wiring layer 160 may include copper having good conductivity, so that a copper contact plug may be formed in the opening 122.

According to some example embodiments of the present invention, thickness of peripheral portions of a metal seed layer in a contact area between the substrate and a cathode of a plating apparatus may be increased to prevent or substantially minimize etching of the metal seed layer during an electroplating process. In particular, a supplementary contact layer may be formed on peripheral portions of the metal seed layer, so electrical current applied to the substrate through the cathode may be uniformly distributed on an entire surface of the substrate. Therefore, a metal wiring layer having a substantially uniform thickness may be formed on the substrate by the electroplating process.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming a metal wiring for a semiconductor device, comprising:
forming a metal-based layer on a substrate, the substrate including at least one conductive structure;
forming a metal seed layer on the metal-based layer;
forming a supplementary contact layer on the metal seed layer along peripheral portions of the substrate, the supplementary contact layer including a supplementary metal having an electrical resistance smaller than or equal to an electrical resistance of the metal seed layer;
loading the substrate into a plating apparatus, such that the supplementary contact layer is in direct contact with a cathode of the plating apparatus; and
forming the metal wiring layer on the metal-based layer by an electroplating process.

2. The method as claimed in claim 1, further comprising forming an insulation layer between the substrate and the metal-based layer.

3. The method as claimed in claim 2, further comprising forming a contact hole through the insulation layer to partially expose the at least one conductive structure, the metal-based layer being conformally formed on the insulation layer.

4. The method as claimed in claim 2, wherein forming the metal-based layer includes forming an anti-diffusion layer on the insulation layer.

5. The method as claimed in claim 4, wherein forming the metal-based layer includes forming at least one metal layer on the insulation layer, the metal layer including one or more of tungsten (W), titanium (Ti), tantalum (Ta), tungsten nitride (WN), titanium nitride (TiN), and tantalum nitride (TaN).

6. The method as claimed in claim 1, wherein forming the metal-based layer and the metal seed layer includes using an atomic layer deposition (ALD) process, a sputtering process, and/or a cyclic chemical vapor deposition (CVD) process.

7. The method as claimed in claim 1, wherein forming the supplementary contact layer includes:
plating the supplementary metal on the metal seed layer along the peripheral portions of the substrate by an electroless plating (ELP) process using a plating solution, the plating solution including a mixture of a salt of the supplementary metal and a reducing agent having weaker reducing ability than the supplementary metal; and
removing a residue of the plating solution from the peripheral portions of the substrate.

8. The method as claimed in claim 7, wherein plating the supplementary metal on the metal seed layer by the ELP process includes:
securing the substrate to a rotation chuck;
arranging an injection nozzle over the peripheral portion of the substrate, the injection nozzle being connected to a reservoir including the plating solution; and
injecting the plating solution onto the metal seed layer while rotating the substrate.

9. The method as claimed in claim 7, wherein plating the supplementary metal on the metal seed layer by the ELP process includes:
immersing the peripheral portion of the substrate into a reservoir including the plating solution; and
rotating the reservoir while the substrate remains stationary.

10. The method as claimed in claim 7, wherein the supplementary metal includes one or more of copper (Cu), nickel (Ni), cobalt (Co), and palladium (Pd), and the reducing agent includes one or more of sodium borohydride, sodium hypophosphite, formalin, hydrazine sulfate, formate, dimethylamine borane (DMAB), diethylamine borane (DEAB), and triethylamine borane (TEAB).

11. The method as claimed in claim 7, wherein the metal seed layer and the supplementary contact layer are formed of a substantially same material.

12. The method as claimed in claim 7, wherein removing the residue of the plating solution includes supplying pure water onto the peripheral portions of the substrate.

13. The method as claimed in claim 7, prior to plating the supplementary metal on the metal seed layer, further comprising:
removing a native oxide layer from the metal seed layer;
activating peripheral portions of the metal seed layer on corresponding peripheral portions of the substrates; and
forming at least one plating nucleus on the peripheral portions of the metal seed layer.

14. The method as claimed in claim 13, wherein activating the peripheral portions of the metal seed layer includes activating surface energy of the peripheral portions of the metal seed layer by a plasma treatment.

15. The method as claimed in claim 14, wherein the plasma treatment is performed using one or more of nitrogen (N₂), hydrogen (H₂), oxygen (O₂), and argon (Ar).

16. The method as claimed in claim 13, wherein forming the plating nucleus includes immersing the activated metal seed layer into an aqueous solution with a nuclear material having smaller ionization tendency than the metal seed layer.

17. The method as claimed in claim 16, wherein the nuclear material includes palladium (Pd).

18. The method as claimed in claim 13, wherein removing the native oxide layer from the metal seed layer includes injecting an alkaline solution onto the peripheral portions of the substrate.

19. The method as claimed in claim 18, wherein the alkaline solution includes an aqueous malic acid solution or an aqueous malonic acid solution.

20. The method as claimed in claim 1, after forming the metal wiring layer, further comprising:
forming a contact plug on the substrate by partially removing the metal-based layer and the metal wiring layer from the substrate; and
forming a protective layer on the contact plug.

21. The method as claimed in claim 20, wherein forming the protective layer includes forming a silver thin layer on the contact plug by a substitution reaction through an ELP process.
